(19) United States
(12) Patent Application Publication
(10) Pub. No.: US 2026/0213672 A1
(43) Pub. Date: Jul. 23, 2026

(54) HIGH PERFORMANCE INTERNAL PIN PROTECTION WITH HIGH DESIGN FLEXIBILITY

(71) Applicant: Infineon Technologies AG, Neubiberg (DE)

(72) Inventors: Patrick Huff, Neubiberg (DE); Gernot Langguth, Oberhaching (DE); Henning Feick, München (DE)

(21) Appl. No.: 19/028,688

(22) Filed: Jan. 17, 2025

(51) Int. Cl. H02M 7/217; H02M 1/32; H02M 7/00

(52) U.S. Cl. CPC H02M 7/217; H02M 7/003; H02M 1/32

(57) ABSTRACT

A silicon controlled rectifier (SCR) circuit includes a first well of a first doping type, including a second well of a second doping type, a third well of the second doping type, and a fourth well of the first doping type; a fifth well of the second doping type adjacent to the first well, including a sixth well of the first doping type, a seventh well of the first doping type, and an eighth well of the second doping type; a first metal stripe contacting the second well and the fourth well; a second metal stripe contacting the third well and the sixth well; and a third metal stripe contacting the seventh well and the eighth well.

### TECHNICAL FIELD

The present invention relates generally to high performance internal pin protection with high design flexibility.

### BACKGROUND

Electrostatic discharge (ESD) protection is known in the art. ESD circuits and protection measures are used to prevent electronic devices and components from damage due to high voltage discharge. ESD protection is generally used for external pads, including reduced ESD protection for pads which have internal package interfaces to other chips. This type of ESD protection requires additional silicon area, which increases chip size. This is especially pronounced for applications with a high number of internal pads, such as in “chiplet” packages, where the area used for ESD protection becomes considerable. Moreover, internal pins are often very sensitive to leakage, parasitic capacitance, and other factors that adversely impact performance.

To minimize the ESD protection footprint and parasitic performance-degrading effects, forward biased diodes are frequently used, representing a reduced silicon area solution in the respective technology. However, one disadvantage of a rail-based diode ESD protection circuit is the need for low impedance connections to associated power clamps. These clamps can be high-ohmically connected. To avoid this, restrictions within the routing network can arise.

State of the art circuits have several disadvantages. A rail-based diode circuit has a high clamping voltage and requires low impedance connection to a power clamp. A diode stack has limitations in footprint size and clamping voltage/ESD performance. A frequently used grounded gate NMOS (GGNMOS) device has drawbacks in leakage, parasitic capacitance, clamping voltage/ESD performance, and footprint size.

An example of a prior art rail-based diode circuit for ESD protection is shown in FIG. 1A. Diode circuit 100A comprises a first diode D1 coupled between a VDD pad and an I/O pad, and a second diode D2 coupled between a VSS pad and the I/O pad. Diode circuit 100A also comprises a first resistor R1A having a first end coupled to the VDD pad, and a second resistor R2A having a first end coupled to the VSS pad. Diode circuit 100A includes a power clamp PC1 coupled between a second end of resistor R1A and a second end of resistor R2A. Resistor R1A and resistor R2A are routing resistances.

Diode circuit 100A includes four discharge paths: a first discharge path 102A through resistor R1A, power clamp PC1, resistor R2A, and second diode D2; a second discharge path 104A through first diode D1, first resistor R1A, power clamp PC1, and second resistor R2A; a third discharge path 106A through first diode D1; and a fourth discharge path 108A through second diode D2.

### SUMMARY

According to an embodiment, a silicon controlled rectifier (SCR) circuit comprises a first well of a first doping type, including a second well of a second doping type, a third well of the second doping type, and a fourth well of the first doping type; a fifth well of the second doping type adjacent to the first well, including a sixth well of the first doping type, a seventh well of the first doping type, and an eighth well of the second doping type; a first metal stripe contacting the second well and the fourth well; a second metal stripe contacting the third well and the sixth well; and a third metal stripe contacting the seventh well and the eighth well.

According to an embodiment, a silicon controlled rectifier (SCR) circuit comprises a first SCR including a first transistor having an emitter coupled to a first power supply pad, a collector coupled to a second power supply pad, and a base, and a second transistor having an emitter coupled to an input/output pad, a collector coupled to the base of the first transistor, and a base coupled to the collector of the first transistor; and a second SCR including a third transistor having an emitter coupled to the input/output pad, a base coupled to the first power supply pad, and a collector, and a fourth transistor having an emitter coupled to the second power supply pad, a collector coupled to the base of the first transistor, and a base coupled to the collector of the third transistor, wherein the first transistor, the second transistor, the third transistor, and the fourth transistor each comprise a device shared between a first well of a first doping type and a second well of a second doping type.

According to an embodiment, a silicon controlled rectifier (SCR) circuit comprises a first SCR coupled between a first power supply pad and an input/output pad; and a second SCR coupled between a second power supply pad and the input/output pad, wherein the first SCR and the second SCR are shared between a first well having a first polarity type and a second well having a second polarity type different from the first polarity type, and wherein the first well and the second well are adjacent wells.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1A is a schematic diagram of a rail-based diode circuit for ESD protection, according to the prior art;

FIG. 1B is a schematic diagram of an SCR circuit for ESD protection, according to an embodiment;

FIG. 1C is a schematic diagram of a power clamp suitable for use with the SCR circuit of FIG. 1B;

FIG. 1D is a plan view of a package layout including first and second integrated circuit dies, wherein the first integrated circuit die includes the SCR circuit of FIG. 1B, according to an embodiment;

FIG. 2 is plan view of an integrated circuit layout of the SRC circuit of FIG. 1B, according to an embodiment;

FIGS. 3A and 3B are additional plan views of a layout of the SRC circuit of FIG. 1B, according to embodiments within the integrated circuit; and

FIGS. 4A and 4B are plan views of additional coupled instances of the integrated circuit layout of FIG. 2, according to embodiments.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. For clarity, the same or similar elements have been designated by corresponding references in the different drawings if not stated otherwise.

According to embodiments, an SCR circuit substitutes the use of separate impedance paths, since local discharge paths are realized with one SCR structure comprising two separate SCRs. These local discharge paths handle all polarities and stress combinations if an ESD event occurs at an internal I/O pad.

In addition, the following embodiment layout features are employed to achieve a minimum device footprint:
A compact SCR layout, combining the high side and the low side SCR;
Shared wells between the high side and the low side SCR;
Replacement of external resistors by internal well resistors;
A side by side layout to allow for optimum metallization; and
Significant width reduction compared to a standard transient-triggered SCR (TTSCR), which is also used as external ESD protection.

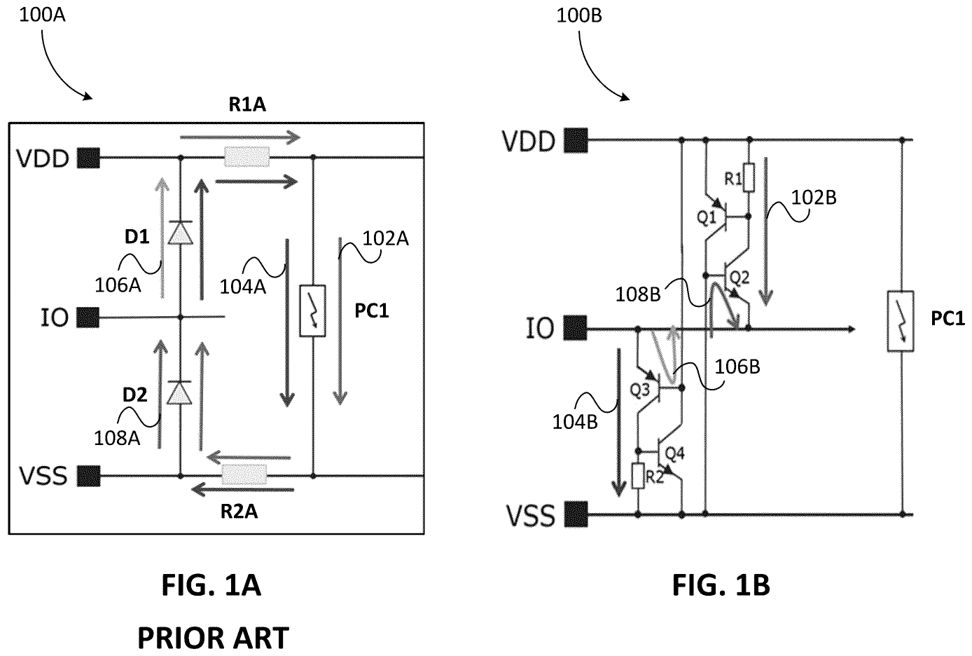

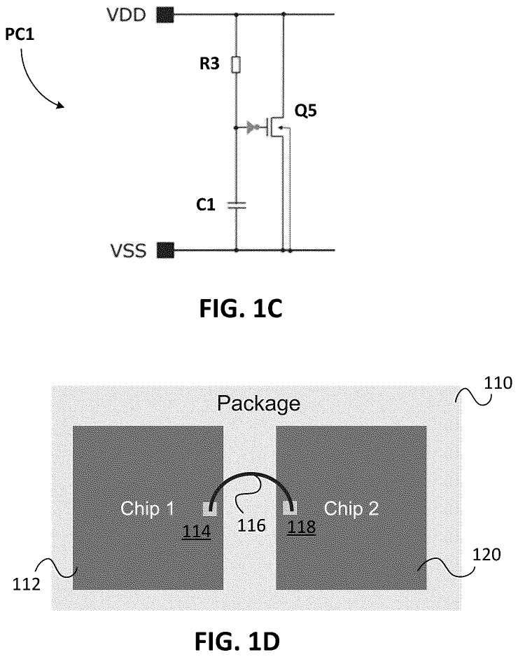

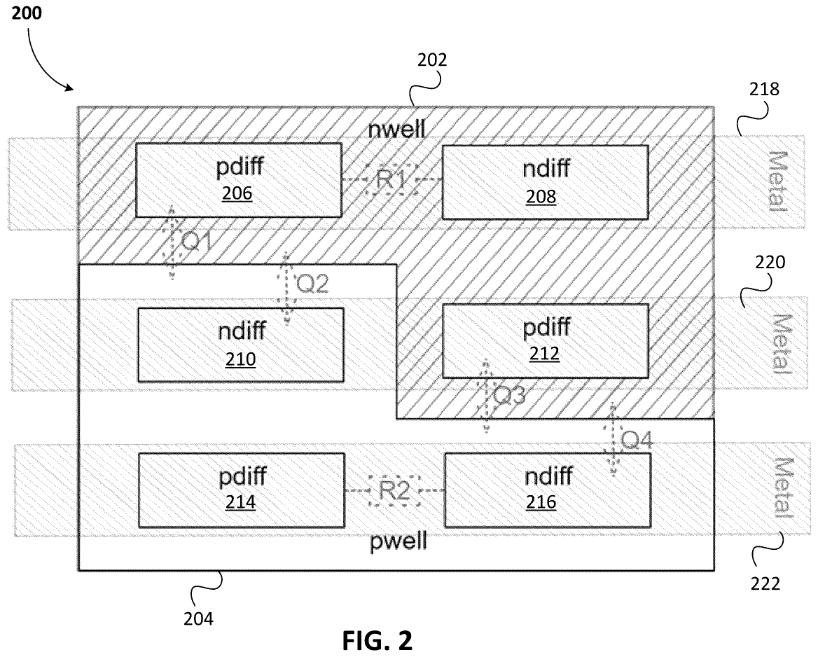

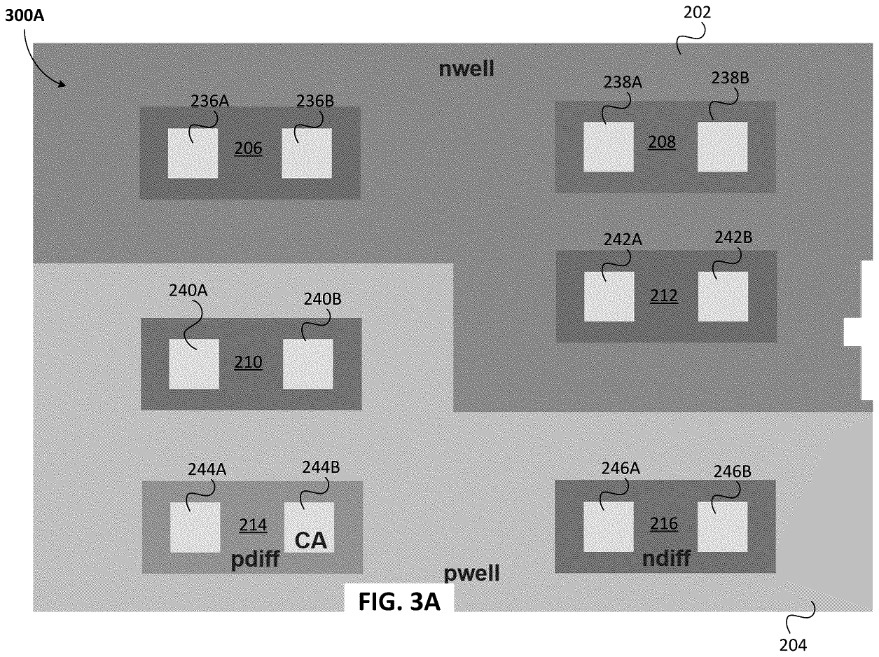

According to embodiments, the resulting SCR circuit footprint becomes comparable to a prior art rail-based diode with minimum size as is shown in FIG. 1A. Advantageously, according to embodiments, the clamping voltage is considerably reduced for the critical stress combinations, for example positive I/O voltage to VSS and negative I/O voltage to VDD compared to the prior art rail-based diode circuit of FIG. 1A.

According to embodiments, the area-reduced SCR layout is changed from vertical to a horizontal side by side arrangement, compared to currently used SCRs. This change allows a simplified metal routing (and improved current carrying capacity), since the number of connected ports is advantageously reduced from six metal stripes to three metal stripes. A fewer number of metal connections thus allows for wider metallization and improved current carrying capacity. In some embodiments, compared to existing SCR and diode circuits, a guard ring is removed, since latch-up protection is advantageously not required for internal pads.

According to embodiments, the two SCRs of the SCR circuit are arranged so that two main wells, an n-type well and a p-type well, of the two SCR structures are be shared, resulting in a significantly smaller footprint. Sub-wells of the main wells provide additional resistive paths between the secondary ports and supply or ground. Advantageously, the currently used polysilicon resistors of the standard SCR, which are used as a secondary trigger mechanism, are not needed and can be removed, resulting in a significantly smaller footprint.

For leakage reduction the sub-well sizes (which are connected to the pads) are kept as small as possible, especially compared to the standard diode-based circuit solutions of the type shown in FIG. 1A.

The above features and additional feature according to embodiments are described below with respect to FIG. 1B through FIG. 3B, wherein FIG. 1B is a schematic diagram of an SCR circuit 100B for ESD protection, according to an embodiment.

Silicon controlled rectifier (SCR) circuit 100B comprises a first SCR including a first transistor Q1 having an emitter coupled to a first power supply pad VDD, a collector coupled to a second power supply pad VSS, and a base, and a second transistor Q2 having an emitter coupled to an input/output pad IO, a collector coupled to the base of the first transistor Q1, and a base coupled to the collector of the first transistor Q1; and a second SCR including a third transistor Q3 having an emitter coupled to the input/output pad IO, a base coupled to the first power supply pad VDD, and a collector, and a fourth transistor Q4 having an emitter coupled to the second power supply pad VSS, a collector coupled to the base of the first transistor Q1, and a base coupled to the collector of the third transistor Q3, wherein the first transistor Q1, the second transistor Q2, the third transistor Q3, and the fourth transistor Q4 each comprise a device shared between a first well of a first doping type and a second well of a second doping type as is explained in further detail below.

In the SCR circuit 100B of FIG. 1B, the first transistor Q1 and the third transistor Q3 each comprise a PNP transistor, and the second transistor Q2 and the fourth transistor Q4 each comprise an NPN transistor. The SCR circuit 100B of FIG. 1B further comprising a first resistor R1 coupled between the base of the first transistor Q1 and the first power supply pad VDD, and a second resistor R2 coupled between the base of the fourth transistor Q4 and the second power supply pad VSS, wherein the first resistor R1 comprises a resistance between first and second sub-wells of the first well, and wherein the second resistor R2 comprises a resistance between first and second sub-wells of the second well in further detail below.

In some embodiments SCR circuit also comprises a power clamp PC1 coupled between the first power supply pad VDD and the second power supply pad VSS. While the power clamp PC1 can comprise any suitable power clamp, a schematic diagram of a representative power clamp PC1 is shown in FIG. 1C. In FIG. 1C, power clamp PC1 includes an MOS transistor Q5 having a drain and source coupled between the first power supply pad VDD and the second power supply pad VSS, and a gate. A resistor R3 is coupled between the first power supply pad VDD and the gate of transistor Q5, and a capacitor C1 is coupled between the second power supply pad VSS and the gate of transistor Q5. In FIG. 1C an inverter is also placed between the junction of resistor R3 and capacitor C1, and the gate of transistor Q5.

The SCR circuit 100B of FIG. 1B can be used in many different product configurations, including various integrated circuit product configurations. FIG. 1D, for example, is a plan view of a package layout of a product package 110 including a first integrated circuit 112 and a second integrated circuit 120, wherein the first integrated circuit 114 includes the SCR circuit 100B of FIG. 1B, according to an embodiment. The first integrated circuit 112 includes an IO pad 114 for providing an ESD protected voltage to a corresponding IO pad 118 on the second integrated circuit 120 through an interconnect 116 such as a metal trace on a circuit board or a gold wire, for example.

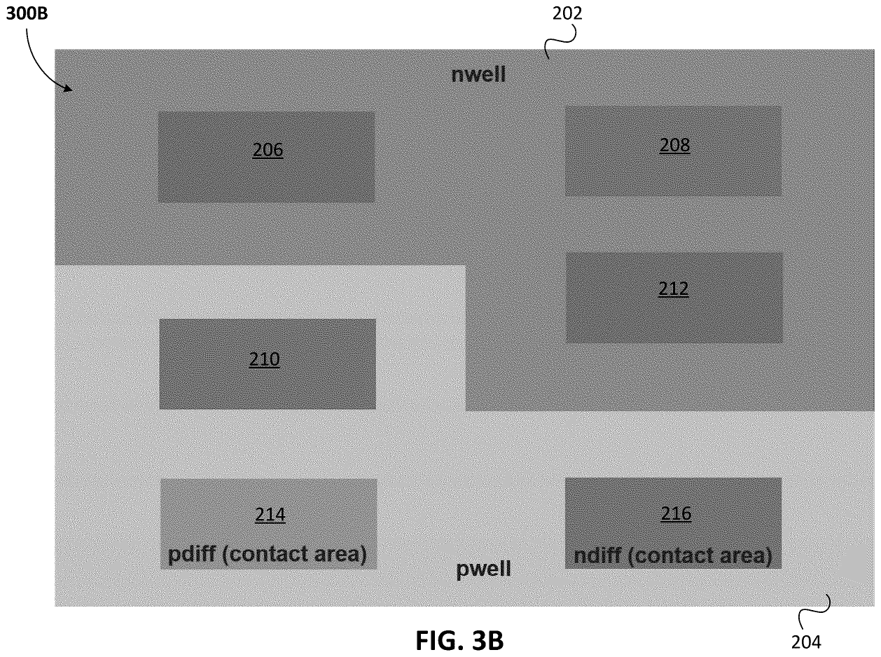

FIG. 2 is plan view of an integrated circuit layout 200 of the SRC circuit 100B of FIG. 1B, according to an embodiment.

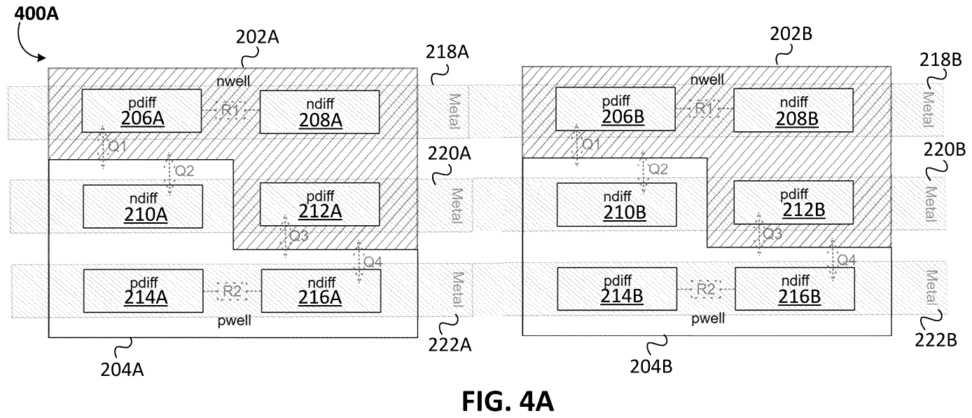

As shown in FIG. 2, SCR circuit 100B comprises well 202 of a first doping type, including a well 206 of a second doping type, well 212 of the second doping type, and well 208 of the first doping type; well 204 of the second doping type adjacent to well 202, including well 210 of the first doping type, well 216 of the first doping type, and well 214 of the second doping type. SCR circuit 100B also comprises a first metal stripe 218 contacting well 206 and well 208; a second metal stripe 220 contacting well 212 and well 210; and a third metal stripe 222 contacting well 216 and well 214. In FIG. 2, the contacts to the various wells are not explicitly shown, but are shown in FIG. 3A and described in further detail below, according to an embodiment. The first metal stripe 218 is coupled to a first power supply pad VDD, the second metal stripe 220 is coupled to an input/output pad IO, and the third metal stripe 222 is coupled to a second power supply pad VSS, in an embodiment.

In the embodiment of FIG. 2, the first doping type comprises an N-type doping type, and the second doping type comprises a P-type doping type. Well 206, well 212, well 208, well 210, well 216, and well 214 each comprise a relatively highly doped well, that is formed with a diffusion process, in an embodiment. Well 202 comprises well 206, well 212, and well 208, and wherein the well 204 comprises well 210, well 216, and well 214, in an embodiment.

In the embodiment of FIG. 2, well 202, well 206, well 204, and well 210 comprise the first transistor Q1 and the second transistor Q2 of the first SCR of SCR circuit 100B. Well 202, well 212, well 204, and well 216 comprise the third transistor Q3 and the fourth transistor Q4 of the second SCR of SCR circuit 100B. In addition, well 206 and well 208 comprise the first resistor R1 of the first SCR of SCR circuit 100B, and well 216 and well 214 comprise a second resistor R2 of the second SCR of SRC circuit 100B.

In an embodiment SCR circuit 100B is fabricated on a single integrated circuit, wherein well 202 comprises an L-shaped well, and wherein well 204 comprises a matching L-shaped well. Other types of matching wells can also be used, such as T-shaped wells, and other matching non-rectangular shapes. It can be seen from the integrated circuit layout 200 of FIG. 2, that a form factor of SCR circuit 100B is determined by a footprint of well 202 and matching well 204.

FIGS. 3A and 3B are additional plan views of an integrated circuit layout of the SRC circuit of FIG. 1B, according to embodiments.

FIG. 3A, in particular, is a plan view of an integrated circuit layout 300A without metallization so that the contact details can be discerned. While the various wells have been previously described with respect to FIG. 2, additional details are now described. Well 206 includes contact 236A and contact 236B. Well 208 includes contact 238A and contact 238B, and well 210 includes contact 240A and contact 240B. Well 212 includes contact 242A and contact 242B. Well 214 includes contact 244A and contact 244B. Finally, well 216 includes contact 246A and contact 248B.

FIG. 3B, in particular, is a plan view of an integrated circuit layout 300B similar to integrated circuit layout 300A, previously described. However, in FIG. 3B, all of the contacts have been removed to emphasize that any contact configuration including one or more contacts can be used for well 206, well 208, well 210, well 212, well 214, and well 216.

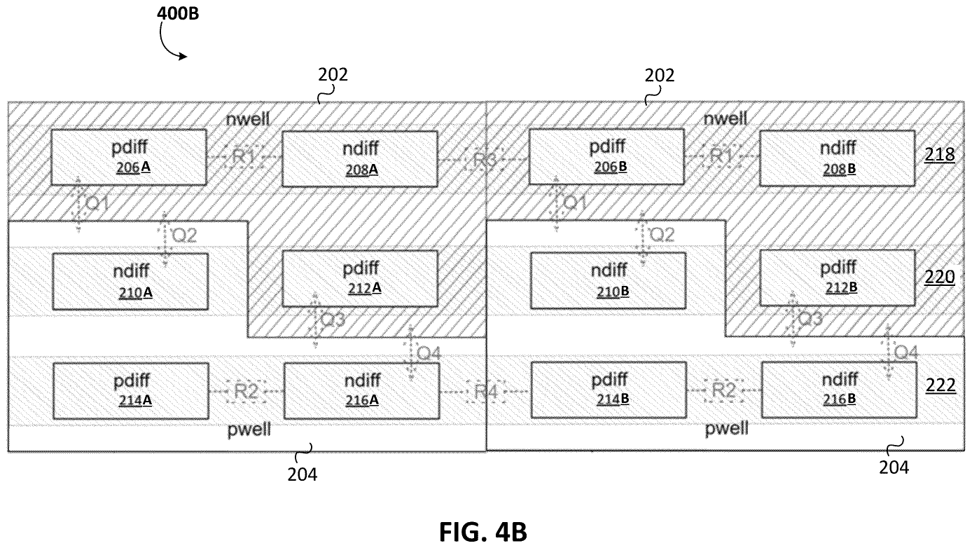

FIGS. 4A and 4B are plan views of additional coupled instances of the integrated SCR circuit layout of FIG. 2, according to embodiments. Additional instances of the SCR circuit layout of FIG. 2 increases ESD protection corresponding to the number of additional instances. The number of additional instances can be increased until a desired ESD target specification is met.

FIG. 4A shows an “independent” placement of an additional instances of the layout shown in FIG. 2, wherein only the metal stripes are merged. Thus, additional instances of the SCR layout results in a linear increment of ESD voltage protection.

As shown in FIG. 4A, SCR circuit layout 400A comprises a first instance of the SCR circuit including well 202A of a first doping type, including a well 206A of a second doping type, well 212A of the second doping type, and well 208A of the first doping type; well 204A of the second doping type adjacent to well 202A, including well 210A of the first doping type, well 216A of the first doping type, and well 214A of the second doping type. The first instance of the SCR circuit also comprises a first metal stripe 218A contacting well 206A and well 208A; a second metal stripe 220A contacting well 212A and well 210A; and a third metal stripe 222 contacting well 216A and well 214A.

As is also shown in FIG. 4A, SCR circuit layout 400A comprises a second instance of the SCR circuit including well 202B of a first doping type, including a well 206B of a second doping type, well 212B of the second doping type, and well 208B of the first doping type; well 204B of the second doping type adjacent to well 202B, including well 210B of the first doping type, well 216B of the first doping type, and well 214B of the second doping type. The first instance of the SCR circuit also comprises a first metal stripe 218B contacting well 206B and well 208B; a second metal stripe 220B contacting well 212B and well 210B; and a third metal stripe 222B contacting well 216B and well 214B.

In FIG. 4A, it should be noted that while the first and second instances of the SCR circuit layout are separated they are operatively coupled together with a plurality of metal stripes. Therefore, the first metal stripe 218A and the first metal stripe 218B are merged together to form a single metal stripe. Similarly, the second metal stripe 220A and the second metal stripe 220B are merged together, and the third metal stripe 222A and the third metal stripe 222B are merged together. While only two instances of an SCR circuit layout are shown in FIG. 4A, any number of additional instances can be used in other embodiments.

FIG. 4B shows the minimum footprint placement 400B including two instances of the SCR circuit layout. It should be noted that the two first wells 202 are adjacent and merged together, and the two second wells 204 are adjacent and merged together. First metal stripe 218, second metal stripe 220, and third metal stripe 222 are also merged together. In the minimum footprint placement 400B two additional resistances R3 and R4 are generated. The two new well resistances somewhat change the startup characteristics of the SCR circuit but the footprint of the SCR circuit is advantageously reduced with respect to the embodiment of FIG. 4A.

Example embodiments of the present invention are summarized here. Other embodiments can also be understood from the entirety of the specification and the claims filed herein.
Example 1. According to an embodiment, a silicon controlled rectifier (SCR) circuit comprises a first well of a first doping type, including a second well of a second doping type, a third well of the second doping type, and a fourth well of the first doping type; a fifth well of the second doping type adjacent to the first well, including a sixth well of the first doping type, a seventh well of the first doping type, and an eighth well of the second doping type; a first metal stripe contacting the second well and the fourth well; a second metal stripe contacting the third well and the sixth well; and a third metal stripe contacting the seventh well and the eighth well.
Example 2. The SCR circuit of Example 1, wherein the first doping type comprises an N-type doping type, and the second doping type comprises a P-type doping type.
Example 3. The SCR circuit of any of the above examples, wherein the second well, the third well, the fourth well, the sixth well, the seventh well, and the eighth well each comprise a highly doped well.
Example 4. The SCR circuit of any of the above examples, wherein the second well, the third well, and the eighth well each comprise a highly doped well in a lightly doped well.
Example 5. The SCR circuit of any of the above examples, wherein the first metal stripe is coupled to a first power supply pad, the second metal stripe is coupled to an input/output pad, and the third metal stripe is coupled to a second power supply pad.
Example 6. The SCR circuit of any of the above examples, wherein the SCR circuit is fabricated on a single integrated circuit.
Example 7. The SCR circuit of any of the above examples, wherein the first well comprises an L-shaped well, and wherein the fifth well comprises a matching L-shaped well.
Example 8. The SCR circuit of any of the above examples, wherein the first well comprises the second well, the third well, and the fourth well, and wherein the fifth well comprises the sixth well, the seventh well, and the eighth well.
Example 9. The SCR circuit of any of the above examples, wherein a form factor of the SCR circuit is determined by a footprint of the first well and the fifth well.
Example 10. The SCR circuit of any of the above examples, wherein the first well, the second well, the fifth well, and the sixth well comprise a first transistor and a second transistor of a first SCR of the SCR circuit.
Example 11. The SCR circuit of any of the above examples, wherein the first well, the third well, the fifth well, and the seventh well comprise a third transistor and a fourth transistor of a second SCR of the SCR circuit.
Example 12. The SCR circuit of any of the above examples, wherein the second well and the fourth well comprise a first resistor of a first SCR of the SCR circuit, and wherein the seventh well and the eighth well comprise a second resistor of a second SCR of the SRC circuit.
Example 13. According to an embodiment, a silicon controlled rectifier (SCR) circuit comprises a first SCR including a first transistor having an emitter coupled to a first power supply pad, a collector coupled to a second power supply pad, and a base, and a second transistor having an emitter coupled to an input/output pad, a collector coupled to the base of the first transistor, and a base coupled to the collector of the first transistor; and a second SCR including a third transistor having an emitter coupled to the input/output pad, a base coupled to the first power supply pad, and a collector, and a fourth transistor having an emitter coupled to the second power supply pad, a collector coupled to the base of the first transistor, and a base coupled to the collector of the third transistor, wherein the first transistor, the second transistor, the third transistor, and the fourth transistor each comprise a device shared between a first well of a first doping type and a second well of a second doping type.
Example 14. The SCR circuit of Example 13, wherein the first transistor and the third transistor each comprise a PNP transistor, and wherein the second transistor and the fourth transistor each comprise an NPN transistor.
Example 15. The SCR circuit of any of the above examples, further comprising a first metal stripe; a second metal stripe; and a third metal stripe, wherein the first SCR of the SCR circuit is coupled between the first metal stripe and the second metal stripe, and wherein the second SCR of the SCR circuit is coupled between the second metal stripe and the third metal stripe.
Example 16. The SCR circuit of any of the above examples, further comprising a first resistor coupled between the base of the first transistor and the first power supply pad, and a second resistor coupled between the base of the fourth transistor and the second power supply pad, wherein the first resistor comprises a resistance between first and second sub-wells of the first well, and wherein the second resistor comprises a resistance between first and second sub-wells of the second well.
Example 17. According to an embodiment, a silicon controlled rectifier (SCR) circuit comprises a first SCR coupled between a first power supply pad and an input/output pad; and a second SCR coupled between a second power supply pad and the input/output pad, wherein the first SCR and the second SCR are shared between a first well having a first polarity type and a second well having a second polarity type different from the first polarity type, and wherein the first well and the second well are adjacent wells.
Example 18. The SCR circuit of Example 17, wherein the first SCR comprises a first transistor, a second transistor, and a first resistor, wherein the second SCR comprises a third transistor, and fourth transistor and a second resistor, wherein the first resistor comprises a resistance between two sub-cells of the first well, and wherein the second resistor comprises a resistance between two sub-cells of the second well.
Example 19. The SCR circuit of any of the above examples, further comprising additional instances of the first well and the adjacent second well operatively coupled to the first well and the second well.
Example 20. The SCR circuit of any of the above examples, wherein the additional instances of the first well and the adjacent second well comprise independent instances operatively coupled through a plurality of metal stripes, or wherein the additional instances comprise adjacent merged instances.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A silicon controlled rectifier (SCR) circuit comprising:
a first well of a first doping type, including a second well of a second doping type, a third well of the second doping type, and a fourth well of the first doping type;
a fifth well of the second doping type adjacent to the first well, including a sixth well of the first doping type, a seventh well of the first doping type, and an eighth well of the second doping type;
a first metal stripe contacting the second well and the fourth well;
a second metal stripe contacting the third well and the sixth well; and
a third metal stripe contacting the seventh well and the eighth well.

2. The SCR circuit of claim 1, wherein the first doping type comprises an N-type doping type, and the second doping type comprises a P-type doping type.

3. The SCR circuit of claim 1, wherein the second well, the third well, the fourth well, the sixth well, the seventh well, and the eighth well each comprise a highly doped well.

4. The SCR circuit of claim 1, wherein the second well, the third well, and the eighth well each comprise a highly doped well in a lightly doped well.

5. The SCR circuit of claim 1, wherein the first metal stripe is coupled to a first power supply pad, the second metal stripe is coupled to an input/output pad, and the third metal stripe is coupled to a second power supply pad.

6. The SCR circuit of claim 5, wherein the SCR circuit is fabricated on a single integrated circuit.

7. The SCR circuit of claim 1, wherein the first well comprises an L-shaped well, and wherein the fifth well comprises a matching L-shaped well.

8. The SCR circuit of claim 1, wherein the first well comprises the second well, the third well, and the fourth well, and wherein the fifth well comprises the sixth well, the seventh well, and the eighth well.

9. The SCR circuit of claim 1, wherein a form factor of the SCR circuit is determined by a footprint of the first well and the fifth well.

10. The SCR circuit of claim 1, wherein the first well, the second well, the fifth well, and the sixth well comprise a first transistor and a second transistor of a first SCR of the SCR circuit.

11. The SCR circuit of claim 1, wherein the first well, the third well, the fifth well, and the seventh well comprise a third transistor and a fourth transistor of a second SCR of the SCR circuit.

12. The SCR circuit of claim 1, wherein the second well and the fourth well comprise a first resistor of a first SCR of the SCR circuit, and wherein the seventh well and the eighth well comprise a second resistor of a second SCR of the SRC circuit.

13. A silicon controlled rectifier (SCR) circuit comprising:
a first SCR including a first transistor having an emitter coupled to a first power supply pad, a collector coupled to a second power supply pad, and a base, and a second transistor having an emitter coupled to an input/output pad, a collector coupled to the base of the first transistor, and a base coupled to the collector of the first transistor; and
a second SCR including a third transistor having an emitter coupled to the input/output pad, a base coupled to the first power supply pad, and a collector, and a fourth transistor having an emitter coupled to the second power supply pad, a collector coupled to the base of the first transistor, and a base coupled to the collector of the third transistor,
wherein the first transistor, the second transistor, the third transistor, and the fourth transistor each comprise a device shared between a first well of a first doping type and a second well of a second doping type.

14. The SCR circuit of claim 13, wherein the first transistor and the third transistor each comprise a PNP transistor, and wherein the second transistor and the fourth transistor each comprise an NPN transistor.

15. The SCR circuit of claim 13, further comprising:
a first metal stripe;
a second metal stripe; and
a third metal stripe,
wherein the first SCR of the SCR circuit is coupled between the first metal stripe and the second metal stripe, and wherein the second SCR of the SCR circuit is coupled between the second metal stripe and the third metal stripe.

16. The SCR circuit of claim 13, further comprising a first resistor coupled between the base of the first transistor and the first power supply pad, and a second resistor coupled between the base of the fourth transistor and the second power supply pad, wherein the first resistor comprises a resistance between first and second sub-wells of the first well, and wherein the second resistor comprises a resistance between first and second sub-wells of the second well.

17. A silicon controlled rectifier (SCR) circuit comprising:
a first SCR coupled between a first power supply pad and an input/output pad; and
a second SCR coupled between a second power supply pad and the input/output pad,
wherein the first SCR and the second SCR are shared between a first well having a first polarity type and a second well having a second polarity type different from the first polarity type, and wherein the first well and the second well are adjacent wells.

18. The SCR circuit of claim 17, wherein the first SCR comprises a first transistor, a second transistor, and a first resistor, wherein the second SCR comprises a third transistor, and fourth transistor and a second resistor, wherein the first resistor comprises a resistance between two sub-cells of the first well, and wherein the second resistor comprises a resistance between two sub-cells of the second well.

19. The SCR circuit of claim 17, further comprising additional instances of the first well and the adjacent second well operatively coupled to the first well and the second well.

20. The SCR circuit of claim 18, wherein the additional instances of the first well and the adjacent second well comprise independent instances operatively coupled through a plurality of metal stripes, or wherein the additional instances comprise adjacent merged instances.
